(19) United States
(12) Patent Application Publication
(10) Pub. No.: US 2025/0255020 A1
(43) Pub. Date: Aug. 7, 2025

(54) CHIP PACKAGE AND MANUFACTURING METHOD THEREOF

(71) Applicant: Xintec Inc., Taoyuan City (TW)

(72) Inventors: Kuei Wei CHEN, Taoyuan City (TW); Yueh Hsien LI, Taoyuan City (TW); Yi-Xuan HUANG, Taoyuan City (TW)

(21) Appl. No.: 19/021,064

(22) Filed: Jan. 14, 2025

Related U.S. Application Data
(60) Provisional application No. 63/549,175, filed on Feb. 2, 2024.

(51) Int. Cl. H10F 39/00

(52) U.S. Cl. CPC H10F 39/804; H10F 39/024; H10F 39/026; H10F 39/805; H10F 39/811

(57) ABSTRACT

A chip package includes a semiconductor substrate, an isolation layer, a redistribution layer, a first protection layer, a second protection layer, and a land conductive structure. The semiconductor substrate has a sensing area, a conductive pad, and a through hole. The redistribution layer is located on the isolation layer, and includes a first section and a second section. The first protection layer is located on the first section, and is located on the isolation layer between the first and second sections. The second protection layer is disposed along the surface of the first protection layer. The transmittance of the first protection layer is less than that of the second protection layer. The land conductive structure is located on the second protection layer and in electrical contact with the redistribution layer.

### CROSS-REFERENCE TO RELATED APPLICATION

This application claims priority to U.S. Provisional Application Ser. No. 63/549,175, filed Feb. 2, 2024, which is herein incorporated by reference.

### BACKGROUND

### Field of Invention

The present disclosure relates to a chip package and a manufacturing method of the chip package.

### Description of Related Art

Generally speaking, a chip package used for image sensing uses a light-transmissive plate to cover a semiconductor substrate, and the light-transmissive plate and the semiconductor substrate are separated by a support element, in which the support element surrounds the sensing area of the semiconductor substrate. Such a configuration may form a cavity among the light-transmissive plate, the support element, and the semiconductor substrate.

However, the entire thickness of the aforementioned chip package is difficult to reduce, and during the manufacturing process, the design of the support element and the choice of the size of the cavity cause limitations for the design rules of the chip package. In addition, the cost of the chip package having the light-transmissive plate and the support element is high, and the chip package requires a ball grid array (BGA) process when disposed on a printed circuit board, which is not conducive to assembly.

### SUMMARY

According to some embodiments of the present disclosure, a chip package includes a semiconductor substrate, an isolation layer, a redistribution layer, a first protection layer, a second protection layer, and a land conductive structure. The semiconductor substrate has a sensing area, a conductive pad, and a through hole, wherein the conductive pad is located in the through hole, and the sensing area and the conductive pad are located on a top surface of the semiconductor substrate. The isolation layer is located on a bottom surface of the semiconductor substrate and a sidewall that surrounds the through hole. The redistribution layer is located on the isolation layer and includes a first section and a second section, wherein the first section is in electrical contact with the conductive pad and extends to the bottom surface of the semiconductor substrate along the sidewall of the through hole, and the second section is located on the bottom surface of the semiconductor substrate. The first protection layer is located on the first section of the redistribution layer, and is located on the isolation layer between the first section and second section of the redistribution layer. The second protection layer is disposed along a surface of the first protection layer, wherein a transmittance of the first protection layer is less than a transmittance of the second protection layer. The land conductive structure is located on the second protection layer, and is in electrical contact with the redistribution layer.

In some embodiments, a color of the first protection layer is different from a color of the second protection layer.

In some embodiments, the color of the first protection layer is black, and the color of the second protection layer is yellow.

In some embodiments, the isolation layer has a portion on an edge of the bottom surface of the semiconductor substrate, and said portion of the isolation layer is free from coverage of the second protection layer so as to be exposed.

In some embodiments, the land conductive structure includes a copper layer, a nickel layer, and a gold layer that are stacked in sequence.

In some embodiments, the second protection layer is in contact with the redistribution layer and the isolation layer.

In some embodiments, the redistribution layer further includes a plurality of third sections, and the third sections are located in the first protection layer.

In some embodiments, the chip package further includes a support element. The support element is located on the top surface of the semiconductor substrate and surrounds the sensing area.

According to some embodiments of the present disclosure, a chip package includes a semiconductor substrate, an isolation layer, a redistribution layer, a first protection layer, a second protection layer, and a land conductive structure. The semiconductor substrate has a sensing area, a conductive pad, and a through hole, wherein the conductive pad is located in the through hole, and the sensing area and the conductive pad are located on a top surface of the semiconductor substrate. The isolation layer is located on a bottom surface of the semiconductor substrate and a sidewall that surrounds the through hole. The redistribution layer is located on the isolation layer and includes a first section and a second section, wherein the first section is in electrical contact with the conductive pad and extends to the bottom surface of the semiconductor substrate along the sidewall of the through hole, and the second section is located on the bottom surface of the semiconductor substrate. The first protection layer is located below the isolation layer and the redistribution layer. The second protection layer is located between the redistribution layer and the first protection layer, wherein a transmittance of the first protection layer is less than a transmittance of the second protection layer. The land conductive structure is located on the second protection layer and is in electrical contact with the redistribution layer, wherein an edge of the land conductive structure extends into the first protection layer.

In some embodiments, the second protection layer is located on the first section and the second section of the redistribution layer, and is located on the isolation layer between the first section and the second section of the redistribution layer.

In some embodiments, a color of the first protection layer is different from a color of the second protection layer.

In some embodiments, the color of the first protection layer is black, and the color of the second protection layer is yellow.

In some embodiments, the isolation layer has a portion on an edge of the bottom surface of the semiconductor substrate, and said portion of the isolation layer is free from coverage of the second protection layer so as to be exposed.

In some embodiments, said portion of the isolation layer, the second protection layer that is on the first section of the redistribution layer, and the first protection layer present a stepped shape.

In some embodiments, the second protection layer is in contact with the redistribution layer and the isolation layer.

In some embodiments, the chip package further includes a support element. The support element is located on the top surface of the semiconductor substrate and surrounds the sensing area.

According to some embodiments of the present disclosure, a manufacturing method of a chip package includes bonding a light-transmissive plate to a semiconductor substrate by using a bonding layer; forming a through hole in the semiconductor substrate, wherein a conductive pad of the semiconductor substrate is located in the through hole; forming an isolation layer on a bottom surface of the semiconductor substrate and a sidewall that surrounds the through hole; forming a redistribution layer located on the isolation layer, wherein the redistribution layer includes a first section and a second section, the first section is in electrical contact with the conductive pad and extends to the bottom surface of the semiconductor substrate along the sidewall of the through hole, and the second section is located on the bottom surface of the semiconductor substrate; forming a first protection layer on the first section of the redistribution layer and on the isolation layer between the first section and second section of the redistribution layer; forming a second protection layer that is disposed along a surface of the first protection layer, wherein a transmittance of the first protection layer is less than a transmittance of the second protection layer; forming a land conductive structure on the second protection layer and in electrical contact with the redistribution layer; removing the bonding layer and the light-transmissive plate; and dicing the semiconductor substrate to form at least one chip package.

In some embodiments, dicing the semiconductor substrate includes forming a trench in the semiconductor substrate by using a laser; and vertically cutting from the trench to the isolation layer on the bottom surface of the semiconductor substrate.

In some embodiments, the manufacturing method of the chip package further includes moving the chip package onto a tape.

According to some embodiments of the present disclosure, a manufacturing method of a chip package includes bonding a light-transmissive plate to a semiconductor substrate by using a bonding layer; forming a through hole in the semiconductor substrate, wherein a conductive pad of the semiconductor substrate is located in the through hole; forming an isolation layer on a bottom surface of the semiconductor substrate and a sidewall that surrounds the through hole; forming a redistribution layer located on the isolation layer, wherein the redistribution layer includes a first section and a second section, the first section is in electrical contact with the conductive pad and extends to the bottom surface of the semiconductor substrate along the sidewall of the through hole, and the second section is located on the bottom surface of the semiconductor substrate; forming a second protection layer on the redistribution layer; forming a land conductive structure on the second protection layer and in electrical contact with the redistribution layer; forming a first protection layer on the second protection layer and an edge of the land conductive structure, wherein a transmittance of the first protection layer is less than a transmittance of the second protection layer; removing the bonding layer and the light-transmissive plate; and dicing the semiconductor substrate to form at least one chip package.

In some embodiments, dicing the semiconductor substrate includes forming a trench in the semiconductor substrate by using a laser; and vertically cutting from the trench to the isolation layer on the bottom surface of the semiconductor substrate.

In some embodiments, the manufacturing method of the chip package further includes moving the chip package onto a tape.

In the aforementioned embodiments of the present disclosure, since the chip package includes the first protection layer, and the second protection layer and the transmittance of the first protection layer is less than the transmittance of the second protection layer, the chip package may have bottom light shielding capability by the first protection layer, and may have capabilities other than light shielding (e.g., waterproof function) by the second protection layer. Moreover, after the formation of the redistribution layer in the chip package, the first protection layer is formed prior to the formation of the second protection layer, such that the first protection layer is located between the semiconductor substrate and the second protection layer. Alternatively, the second is formed prior to the formation of the first protection layer, such that the second protection layer is located between the semiconductor substrate and the first protection layer. Because the chip package has no support element and light-transmissive plate, costs may be saved and thickness is thin, and the chip package is not limited by the design rules of support element design (Dam design) and cavity size, which is more flexible in design.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a chip package according to one embodiment of the present disclosure.

FIG. 1B is a cross-sectional view of a chip package according to another embodiment of the present disclosure.

FIGS. 2 to 10 are cross-sectional views at intermediate stages of a manufacturing method of the chip package of FIG. 1A.

FIG. 11 is a partially enlarged view of the chip package of FIG. 10 near a scribe line.

FIG. 12 is a schematic view of the chip package of FIG. 10 after being moved onto a tape.

FIG. 13 is a cross-sectional view of a chip package according to another embodiment of the present disclosure.

FIG. 14 is a cross-sectional view at an intermediate stage of a manufacturing method of the chip package of FIG. 13.

FIG. 15 is a cross-sectional view of a chip package according to still another embodiment of the present disclosure.

FIGS. 16 to 18 are cross-sectional views at intermediate stages of a manufacturing method of the chip package of FIG. 15.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

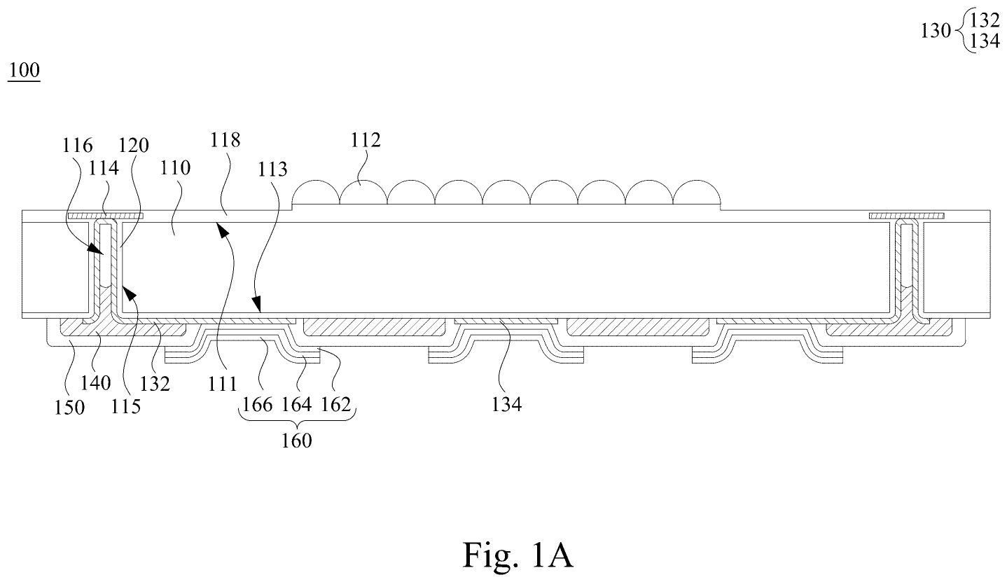

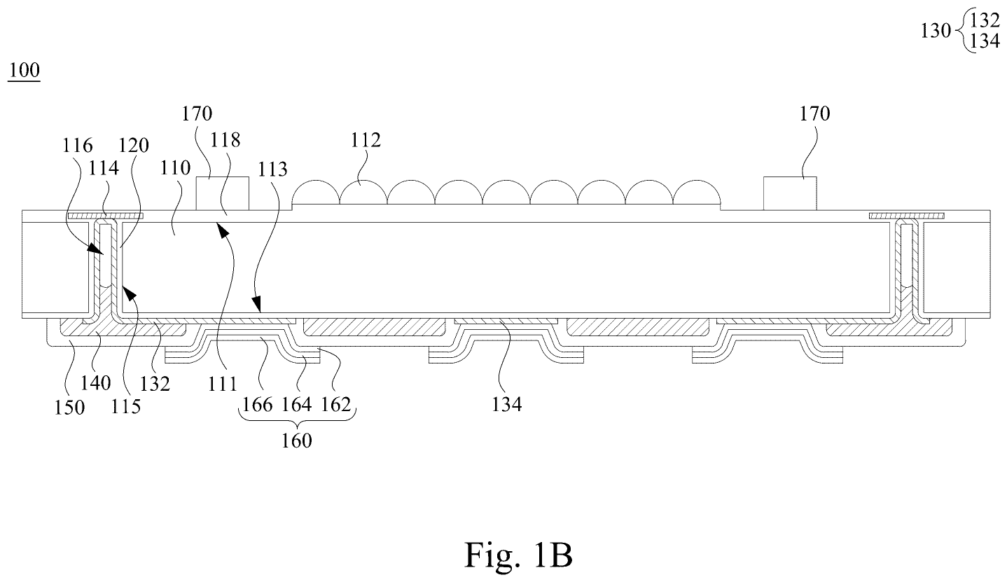

FIG. 1A is a cross-sectional view of a chip package 100 according to one embodiment of the present disclosure. The chip package 100 includes a semiconductor substrate 110, an isolation layer 120, a redistribution layer 130, a first protection layer 140, a second protection layer 150, and a land conductive structure 160. The semiconductor substrate 110 has a sensing area 112, a conductive pad 114, and a through hole 116. The material of the semiconductor substrate 110 may include silicon, and is an image sensor. The conductive pad 114 is located in the through hole 116. The sensing area 112 and the conductive pad 114 are located on a top surface 111 of the semiconductor substrate 110. The isolation layer 120 is located on a bottom surface 113 of the semiconductor substrate 110 and a sidewall 115 that surrounds the through hole 116. The redistribution layer 130 is located on the isolation layer 120 and includes a first section 132 and a second section 134. The first section 132 of the redistribution layer 130 is in electrical contact with the conductive pad 114, and extends to the bottom surface 113 of the semiconductor substrate 110 along the sidewall 115 of the through hole 116. The second section 134 of the redistribution layer 130 is located on the bottom surface 113 of the semiconductor substrate 110. A portion of the first protection layer 140 is located on the first section 132 of the redistribution layer 130, and another portion of the first protection layer 140 is located on the isolation layer 120 between the first section 132 and second section 134 of the redistribution layer 130. The second protection layer 150 is disposed along the surface of the first protection layer 140. The transmittance of the first protection layer 140 is less than the transmittance of the second protection layer 150. The land conductive structure 160 is located on the second protection layer 150, and is in electrical contact with the redistribution layer 130.

In this embodiment, the color of the first protection layer 140 is different from the color of the second protection layer 150. For example, the color of the first protection layer 140 may be black, and is configured to block and absorb ambient noise light to improve the sensing accuracy of the sensing area 112. The color of the second protection layer 150 may be yellow, and is configured to prevent moisture from entering the chip package 100.

Specifically, since the chip package 100 includes the first protection layer 140 and the second protection layer 150, and the transmittance of the first protection layer 140 is less than the transmittance of the second protection layer 150, the chip package 100 may have bottom light shielding capability by the first protection layer 140, and may have capabilities other than light shielding (e.g., waterproof function) by the second protection layer 150, Moreover, in this embodiment, after the formation of the redistribution layer 130 in the chip package 100, the first protection layer 140 is formed prior to the formation of the second protection layer 150, such that the first protection layer 140 is located between the semiconductor substrate 110 and the second protection layer 150. Because the chip package 100 has no support element and light-transmissive plate, costs may be saved and thickness is thin, and the chip package 100 is not limited by the design rules of support element design (Dam design) and cavity size, which is more flexible in design.

In this embodiment, the isolation layer 120 has a portion on the edge of the bottom surface 113 of the semiconductor substrate 110, and said portion of the isolation layer 120 is free from coverage of the second protection layer 150 so as to be exposed. The second protection layer 150 is in contact with the redistribution layer 130 and the isolation layer 120.

Furthermore, the land conductive structure 160 includes a copper layer 162, a nickel layer 164, and a gold layer 166 that are stacked in sequence. Because the chip package 100 has the land conductive structure 160, a ball grid array process is unneeded when the chip package 100 is assembled to a printed circuit board, which facilitates for assembly.

FIG. 1B is a cross-sectional view of a chip package 100 according to another embodiment of the present disclosure. The difference between this embodiment and the embodiment of FIG. 1A is that the chip package 100 of FIG. 1B further includes a support element 170. The support element 170 is located on the top surface 111 of the semiconductor substrate 110, and surrounds the sensing area 112.

It is to be noted that the connection relationships, the materials, and the advantages of the elements described above will not be repeated in the following description. In the following description, a manufacturing method of the chip package 100 will be explained.

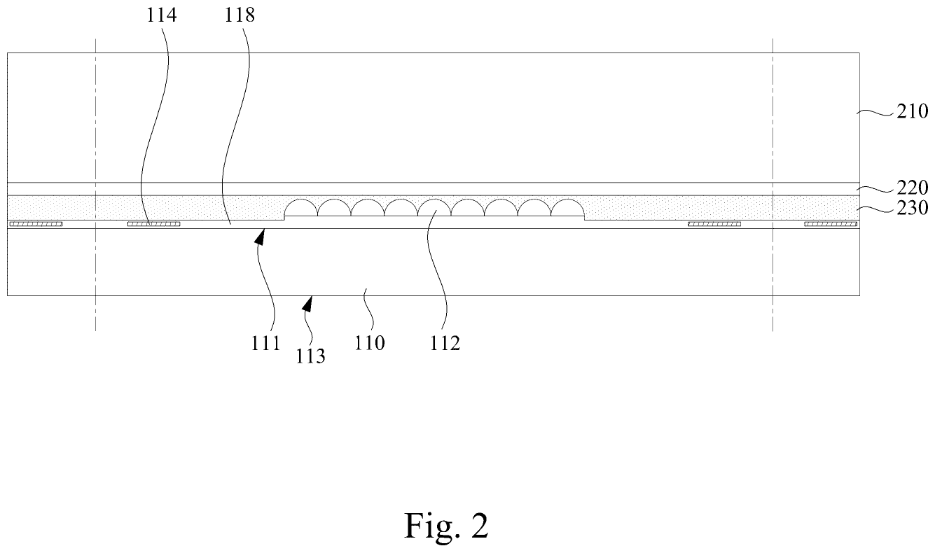

FIGS. 2 to 10 are cross-sectional views at intermediate stages of a manufacturing method of the chip package 100 of FIG. 1A. Referring to FIG. 2, a tape 220, such as a double sided tape, is adhered to the bottom surface of a light-transmissive plate 210. Moreover, a bonding layer 230 is formed on the top surface 111 of the semiconductor substrate 110. The semiconductor substrate 110 shown in FIG. 2 to FIG. 9 is in wafer level, and has not yet undergone a dicing process. Thereafter, the light-transmissive plate 210 is bonded to the semiconductor substrate 110 by using the bonding layer 230 so as to obtain the structure of FIG. 2. In some embodiment, a grinding process may be performed on the bottom surface 113 of the semiconductor substrate 110 after bonding the light-transmissive plate 210 to the semiconductor substrate 110.

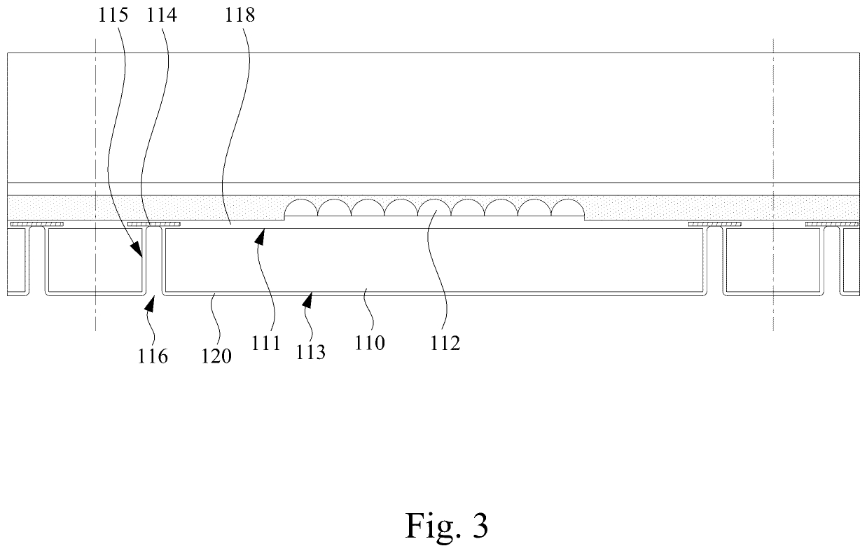

Referring to FIG. 3, thereafter, the through hole 116 is formed in the semiconductor substrate 110, and the conductive pad 114 of the semiconductor substrate 110 is located in the through hole 116. The conductive pad 114 is exposed through the through hole 116. Thereafter, the isolation layer 120 is formed on the bottom surface 113 of the semiconductor substrate 110 and the sidewall 115 that surrounds the through hole 116. The formation of the isolation layer 120 may include forming the isolation layer 120 to cover the conductive pad 114 in the through hole 116, the sidewall 115 of the through hole 116, and the bottom surface 113 of the semiconductor substrate 110, and etching the isolation layer 120 on the conductive pad 114. Etching the isolation layer 120 may be performed by blanket etch or patterning the isolation layer 120 by using photoresist. Blanket etch may enable the isolation layer 120 to be perpendicular to the conductive pad 114. Using the photoresist to pattern the isolation layer 120 may enable an end of the isolation layer 120 adjacent to the conductive pad 114 to be inclined.

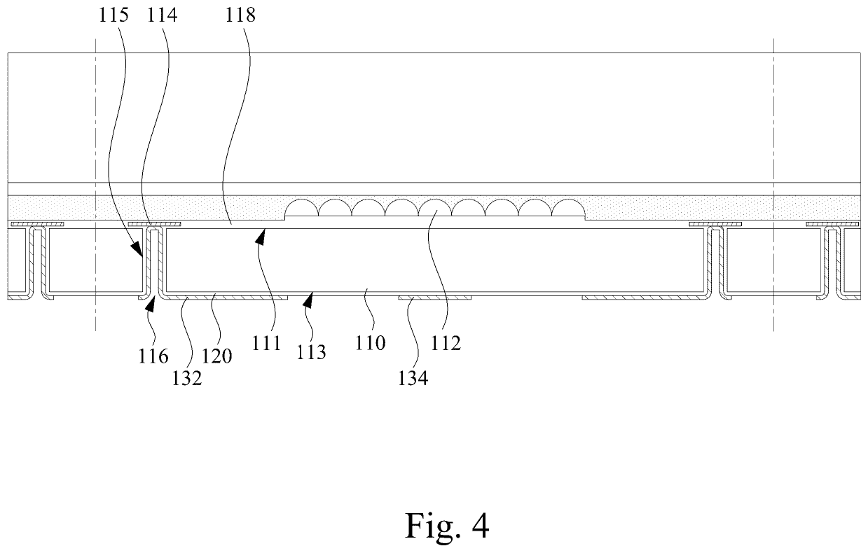

As shown in FIG. 4, after the formation of the isolation layer 120, the redistribution layer 130 can be formed located on the isolation layer 120, in which the redistribution layer 130 may include the first section 132 and the second section 134 after patterning. The first section 132 of the redistribution layer 130 is in electrical contact with the conductive pad 114, and extends to the bottom surface 113 of the semiconductor substrate 110 along the sidewall 115 of the through hole 116. The second section 134 of the redistribution layer 130 is located on the bottom surface 113 of the semiconductor substrate 110.

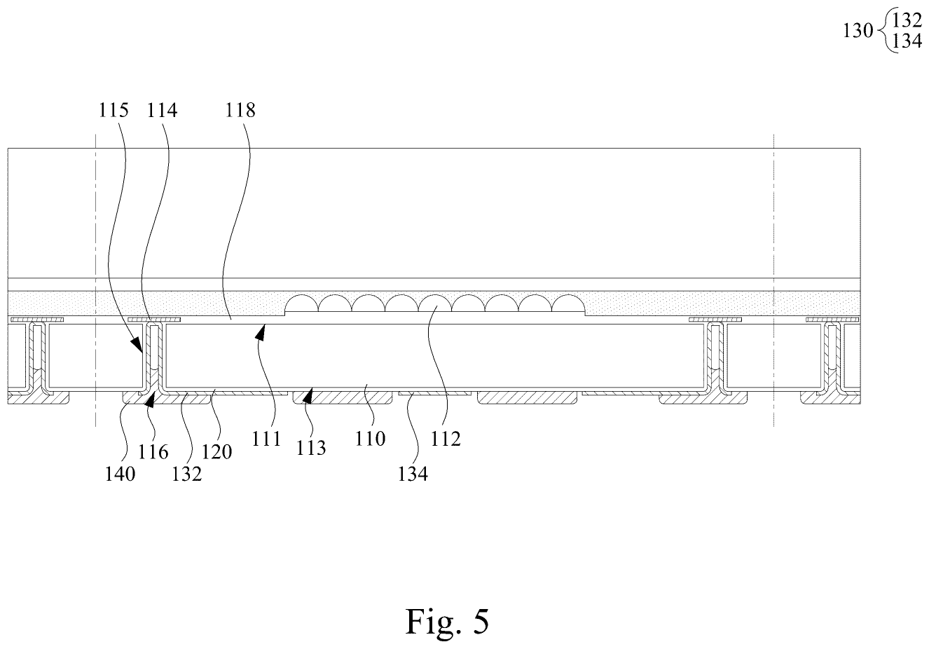

As shown in FIG. 5, thereafter the first protection layer 140 is formed on the first section 132 of the redistribution layer 130 and on the isolation layer 120 between the first section 132 and second section 134 of the redistribution layer 130. The first protection layer 140 on the first section 132 covers the through hole 116. The first protection layer 140 between the first section 132 and second section 134 is located on the isolation layer 120, said first protection layer 140 and the first section 132 have a gap therebetween, and said first protection layer 140 and the second section 134 have a gap therebetween.

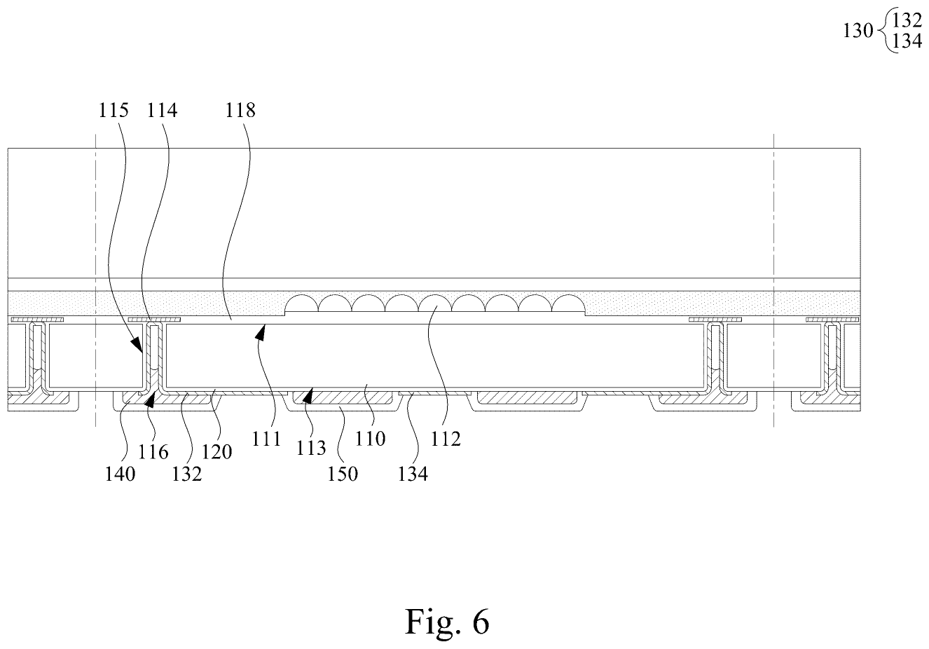

As shown in FIG. 6, after the formation of the first protection layer 140, the second protection layer 150 is formed. The second protection layer 150 is disposed along the surfaces (e.g., the sidewall and the bottom surface) of the first protection layer 140, in which the transmittance of the first protection layer 140 is less than the transmittance of the second protection layer 150. For example, the color of the first protection layer 140 is black, and the color of the second protection layer 150 is yellow. The second protection layer 150 may cover a portion of the redistribution layer 130 and a portion of the isolation layer 120, and thus the first section 132 and second section 134 of the redistribution layer 130 are exposed.

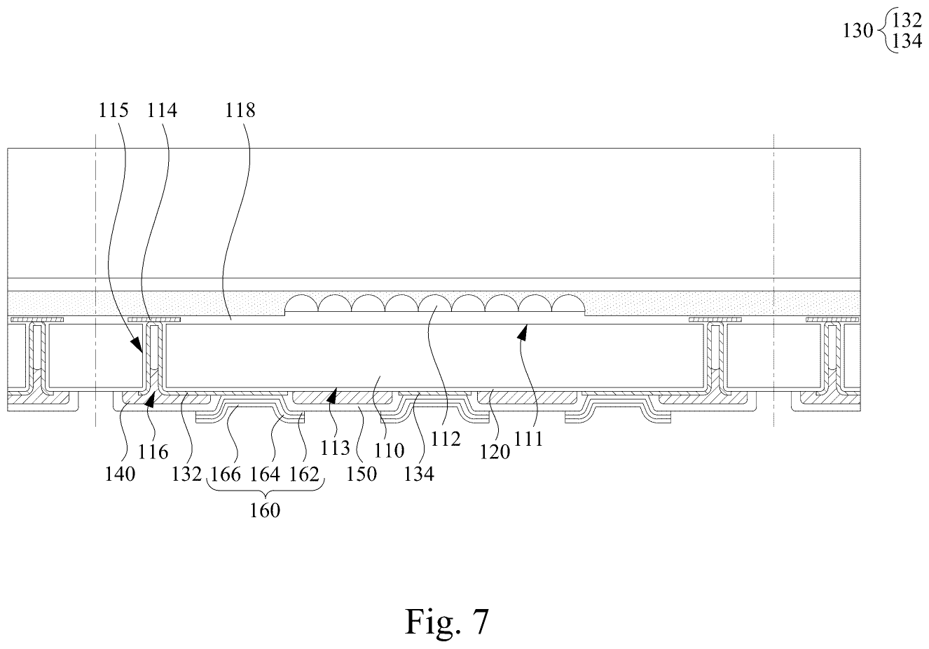

As shown in FIG. 7, thereafter, the land conductive structure 160 is formed on the second protection layer 150 and is in electrical contact with the redistribution layer 130. The land conductive structure 160 is located on the first section 132 and second section 134 of the redistribution layer 130 exposed from the second protection layer 150. In this embodiment, the land conductive structure 160 includes the copper layer 162, the nickel layer 164, and the gold layer 166, but the present disclosure is not limited in this regard.

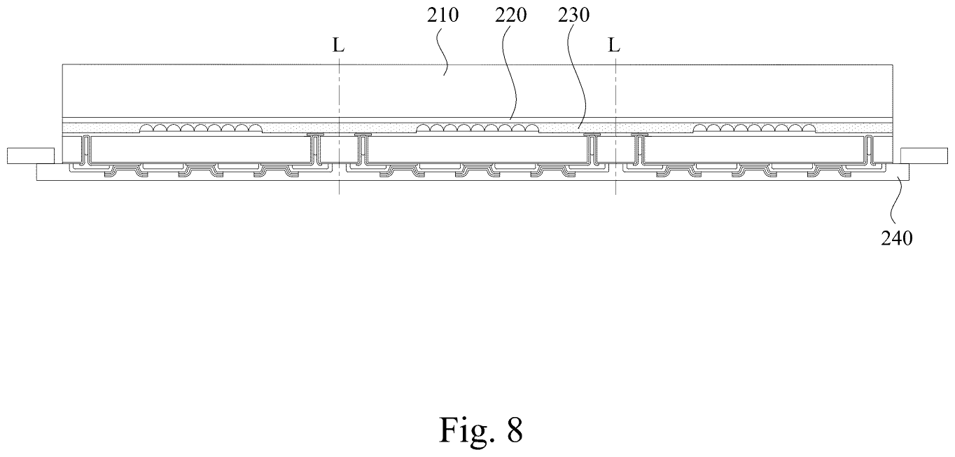

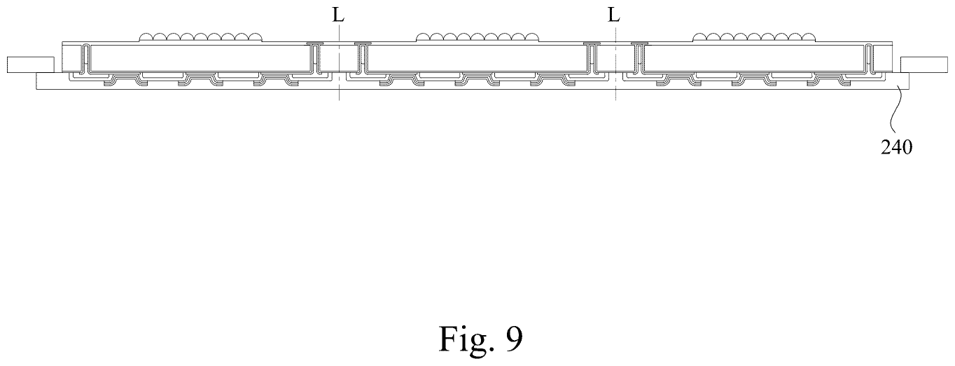

As shown in FIG. 8 and FIG. 9, thereafter, the structure of FIG. 7 may be attached to a tape 240, and the bonding layer 230, the tape 220 and the light-transmissive plate 210 are removed. The light-transmissive plate 210 and the tape 220 may be separated from the bonding layer 230 by tearing, and the bonding layer 230 is removed by cleaning. As a result, the structure of FIG. 9 can be obtained.

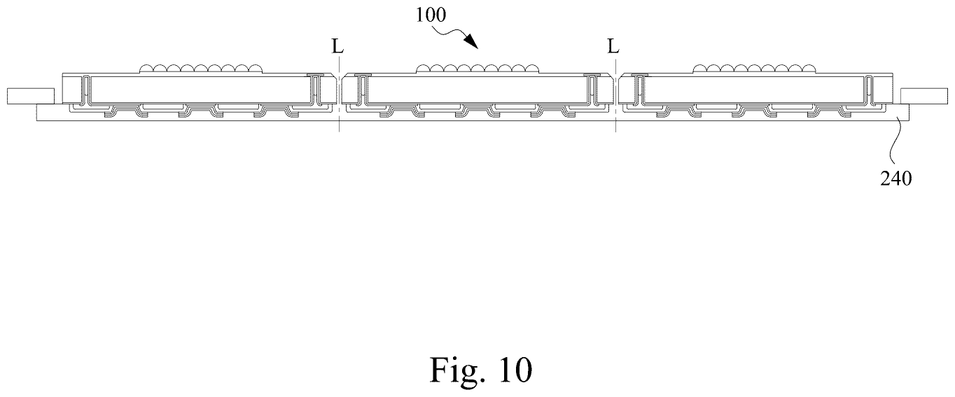

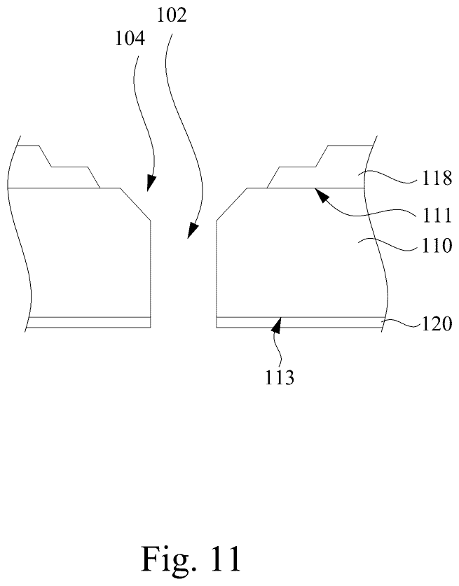

FIG. 11 is a partially enlarged view of the chip package 100 of FIG. 10 near a scribe line 102. As shown in FIG. 10 and FIG. 11, thereafter, the semiconductor substrate 110 may be diced along a dotted line L to form at least one chip package 100 of FIG. 1A. In this embodiment, dicing the semiconductor substrate 110 includes forming a trench 104 in the semiconductor substrate 110 by using a laser, and vertically cutting from the trench 104 to the isolation layer 120 on the bottom surface 113 of the semiconductor substrate 110, thereby forming the scribe line 102. The formations of the trench 104 and the scribe line 102 are performed such that the corner of the semiconductor substrate 110 and an isolation layer 118 that is on the top surface 111 of the semiconductor substrate 110 present a stepped structure.

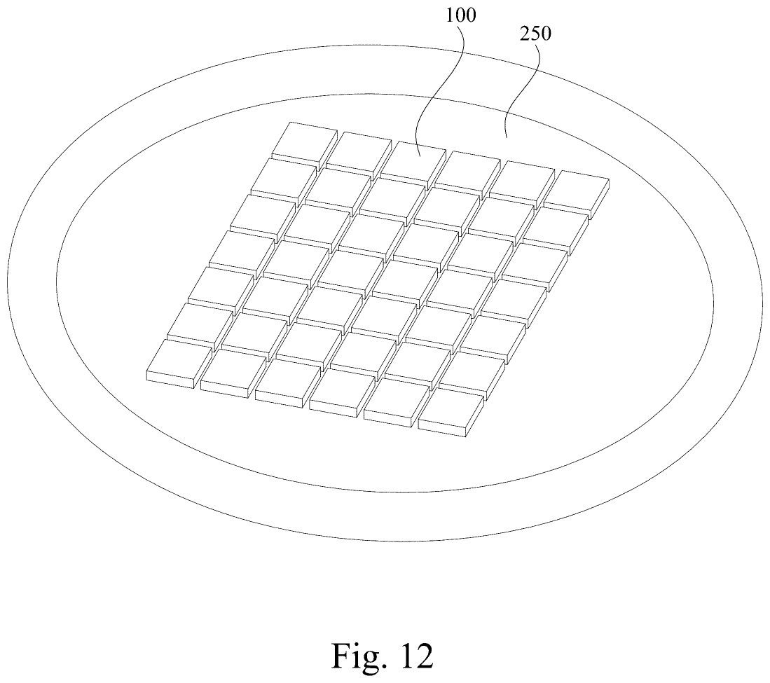

FIG. 12 is a schematic view of the chip package 100 of FIG. 10 after being moved onto a tape 250. Thereafter, the chip package 100 may be moved onto the another tape 250, thereby rearranging to construct a wafer with another size. For example, the tape 240 of FIG. 10 may be attached by a 12-inch wafer, and the tape 250 of FIG. 12 may be attached by an 8-inch wafer.

It is to be noted that the connection relationships, the materials, and the advantages of the elements described above will not be repeated in the following description. In the following description, other types of chip packages will be explained.

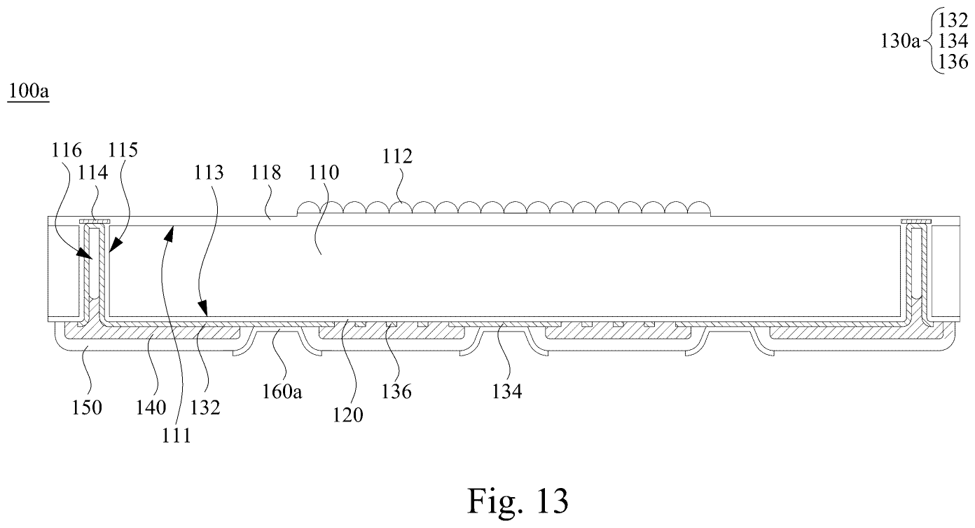

FIG. 13 is a cross-sectional view of a chip package 100a according to another embodiment of the present disclosure. The chip package 100a includes the semiconductor substrate 110, the isolation layer 120, a redistribution layer 130a, the first protection layer 140, the second protection layer 150, and a land conductive structure 160a. The land conductive structure 160a may be a composite layer including the copper layer 162, the nickel layer 164, and the gold layer 166 shown in FIG. 7, for example. The difference between this embodiment and the embodiment of FIG. 1A is that the first protection layer 140 of the chip package 100a covers the end portion of each of the sections of the redistribution layer 130a (e.g., the first section 132 and second section 134). In such a design, there is no gap between the first protection layer 140 and each end portion of the redistribution layer 130a. Therefore, even if the length of the land conductive structure 160a on the second protection layer 150 is less than that of the land conductive structure 160 of FIG. 7, the chip package 100a can still have good light shielding effect. In some embodiments, the redistribution layer 130a further includes plural third sections 136. The third sections 136 of the redistribution layer 130a are located in the first protection layer 140. The first protection layer 140 surrounding the third section 136 is located between the first section 132 and second section 134.

In another embodiment, the chip package 100a may include the support element 170 (see FIG. 1B) on the top surface 111 of the semiconductor substrate 110.

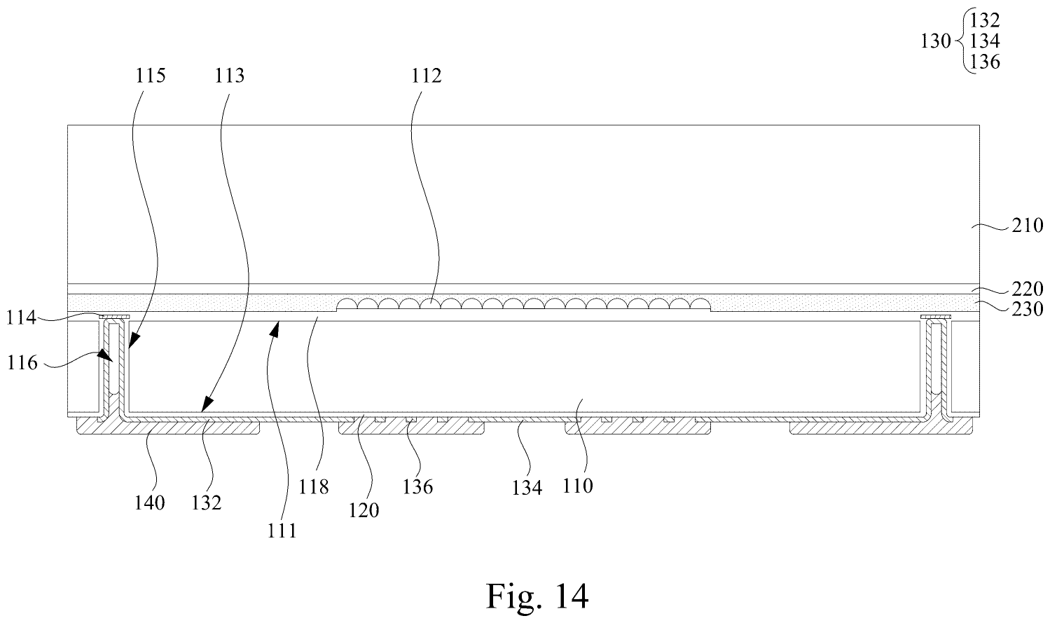

FIG. 14 is a cross-sectional view at an intermediate stage of a manufacturing method of the chip package 100a of FIG. 13. The steps of manufacturing the chip package 100a before forming the redistribution layer 130a and after forming the first protection layer 140 are similar to those of manufacturing the aforementioned chip package 100, and will not be repeated in the following description. After the formation of the isolation layer 120, the redistribution layer 130a may be formed on the isolation layer 120, in which the redistribution layer 130a through patterning may include the first section 132, the second section 134, and the third section 136. Thereafter, the first protection layer 140 is formed on the first section 132 of the redistribution layer 130a and on the isolation layer 120 between the first section 132 and the second section 134 of the redistribution layer 130a, such that the first protection layer 140 surrounds the third section 136.

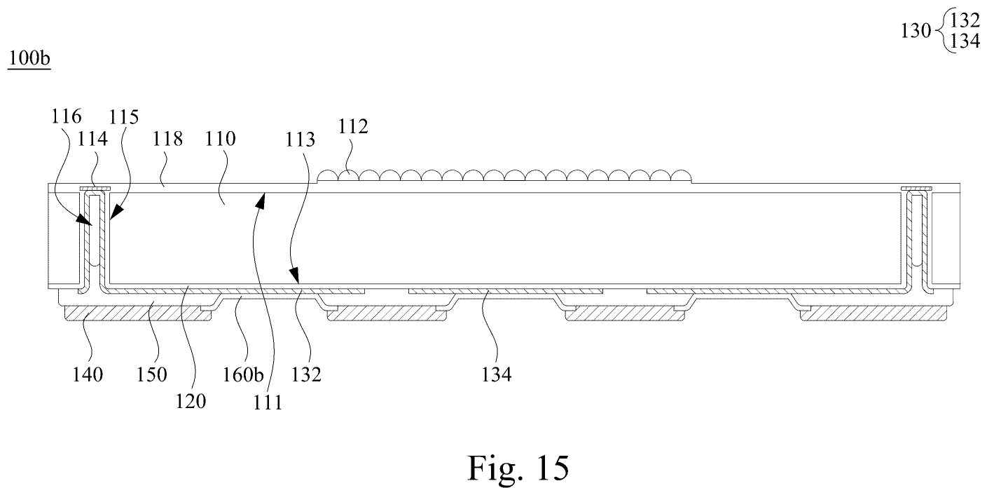

FIG. 15 is a cross-sectional view of a chip package 100b according to still another embodiment of the present disclosure. The chip package 100b includes the semiconductor substrate 110, the isolation layer 120, the redistribution layer 130, the first protection layer 140, the second protection layer 150, and a land conductive structure 160b. The land conductive structure 160b may be a composite layer including the copper layer 162, the nickel layer 164, and the gold layer 166 shown in FIG. 7, for example. The semiconductor substrate 110 has the sensing area 112, the conductive pad 114, and the through hole 116. The conductive pad 114 is located in the through hole 116. The sensing area 112 and the conductive pad 114 are located on the top surface 111 of the semiconductor substrate 110. The isolation layer 120 is located on the bottom surface 113 of the semiconductor substrate 110 and the sidewall 115 that surrounds the through hole 116. The redistribution layer 130 is located on the isolation layer 120 and includes the first section 132 and the second section 134. The first section 132 is in electrical contact with the conductive pad 114 and extends to the bottom surface 113 of the semiconductor substrate 110 along the sidewall 115 of the through hole 116. The second section 134 is located on the bottom surface 113 of the semiconductor substrate 110. The first protection layer 140 is located below the isolation layer 120 and the redistribution layer 130. The second protection layer 150 is located between the redistribution layer 130 and the first protection layer 140. The transmittance of the first protection layer 140 is less than the transmittance of the second protection layer 150. The land conductive structure 160b is located on the second protection layer 150 and is in electrical contact with the redistribution layer 130. The edge of the land conductive structure 160b extends into the first protection layer 140.

In this embodiment, the color of the first protection layer 140 is different from the color of the second protection layer 150. For example, the color of the first protection layer 140 is black, and the color of the second protection layer 150 is yellow. The second protection layer 150 is located on the first section 132 and the second section 134 of the redistribution layer 130, and is located on the isolation layer 120 between the first section 132 and the second section 134 of the redistribution layer 130. The second protection layer 150 is in contact with the redistribution layer 130 and the isolation layer 120.

In addition, the isolation layer 120 has a portion on the edge of the bottom surface 113 of the semiconductor substrate 110, and said portion of the isolation layer 120 is free from coverage of the second protection layer 150 so as to be exposed, such as the isolation layer 120 in the lower left corner of FIG. 15. Said portion of the isolation layer 120, the second protection layer 150 that is on the first section 132 of the redistribution layer 130, and the first protection layer 140 present a stepped shape.

In another embodiment, the chip package 100b may include the support element 170 (see FIG. 1B) on the top surface 111 of the semiconductor substrate 110.

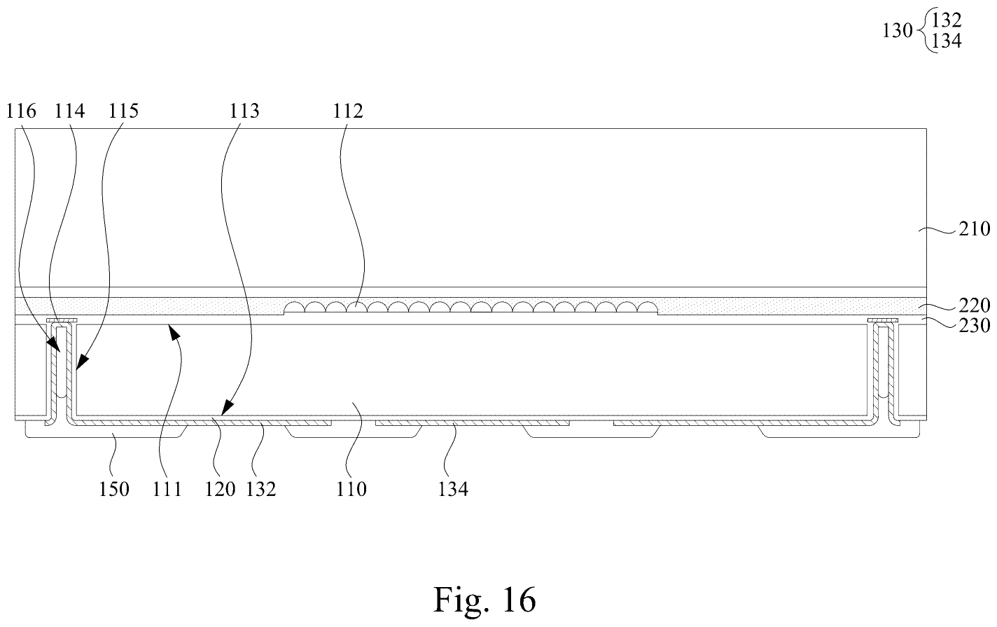

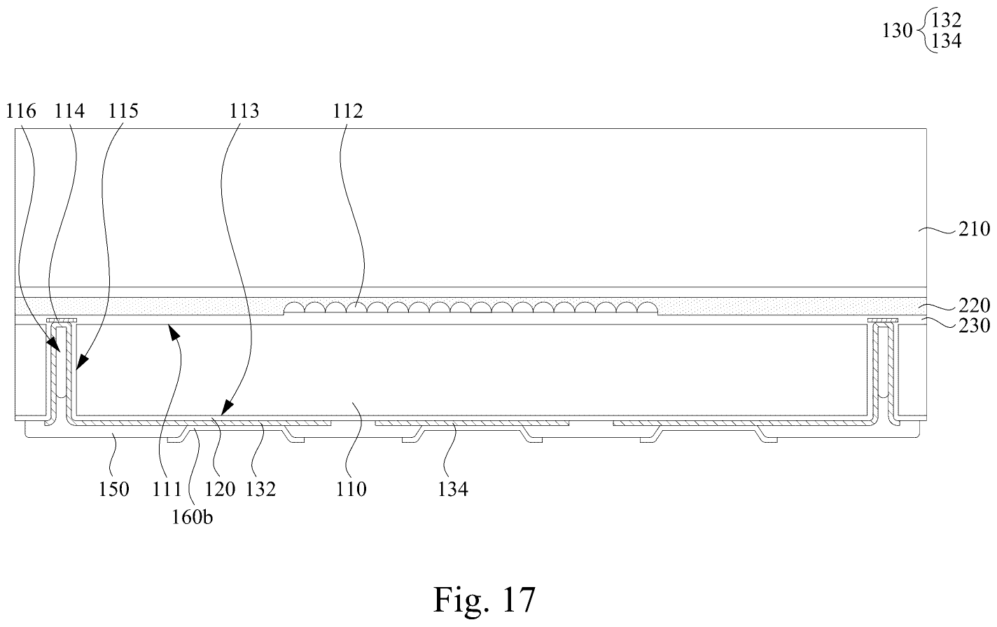

FIGS. 16 to 18 are cross-sectional views at intermediate stages of a manufacturing method of the chip package 100b of FIG. 15. The steps of manufacturing the chip package 100b before forming the second protection layer 150 are similar to those of manufacturing the aforementioned chip package 100, and will not be repeated in the following description. As shown in FIG. 16 and FIG. 17, after the formation of the redistribution layer 130, the second protection layer 150 is formed on the redistribution layer 130. Thereafter, the land conductive structure 160b is on the second protection layer 150 and in electrical contact with the redistribution layer 130.

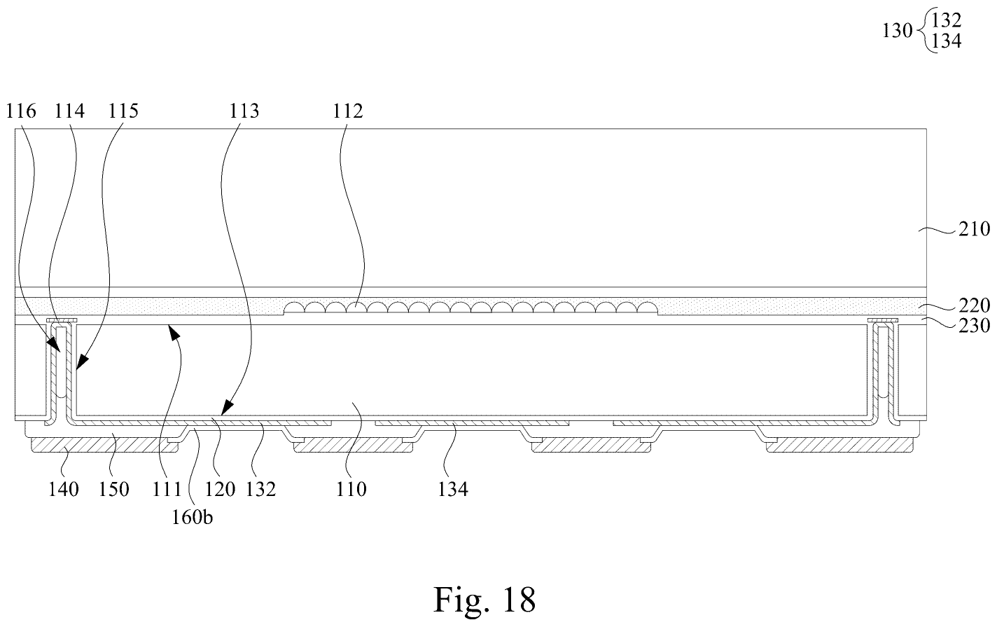

As shown in FIG. 18, after the formation of the land conductive structure 160b, the first protection layer 140 may be formed on the second protection layer 150 and the edge of the land conductive structure 160b, in which the transmittance of the first protection layer 140 is less than the transmittance of the second protection layer 150. In this embodiment, after the formation of the redistribution layer 130, the second protection layer 150 is formed prior to the formation of the first protection layer 140, such that the second protection layer 150 is located between the semiconductor substrate 110 and the first protection layer 140.

After the structure of FIG. 18 is formed, the aforementioned steps shown in FIG. 8 to FIG. 12 may be performed. In other words, the structure of FIG. 18 may be attached to the tape 240 (see FIG. 8), and the bonding layer 230, the tape 220 and the light-transmissive plate 210 are removed. Thereafter, the semiconductor substrate 110 is diced to form at least one chip package 100b. Dicing the semiconductor substrate 110 includes forming the trench 104 (see FIG. 11) in the semiconductor substrate 110 by using a laser, and vertically cutting from the trench 104 to the isolation layer 120 on the bottom surface 113 of the semiconductor substrate 110. After the chip package 100b (see FIG. 15) is formed by dicing, the chip package 100b may be moved onto the another tape 250 (see FIG. 12).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a semiconductor substrate having a sensing area, a conductive pad, and a through hole, wherein the conductive pad is located in the through hole, and the sensing area and the conductive pad are located on a top surface of the semiconductor substrate;
an isolation layer located on a bottom surface of the semiconductor substrate and a sidewall that surrounds the through hole;
a redistribution layer located on the isolation layer and comprising a first section and a second section, wherein the first section is in electrical contact with the conductive pad and extends to the bottom surface of the semiconductor substrate along the sidewall of the through hole, and the second section is located on the bottom surface of the semiconductor substrate;
a first protection layer located on the first section of the redistribution layer and located on the isolation layer between the first section and second section of the redistribution layer;
a second protection layer disposed along a surface of the first protection layer, wherein a transmittance of the first protection layer is less than a transmittance of the second protection layer; and
a land conductive structure located on the second protection layer and in electrical contact with the redistribution layer.

2. The chip package of claim 1, wherein a color of the first protection layer is different from a color of the second protection layer.

3. The chip package of claim 2, wherein the color of the first protection layer is black, and the color of the second protection layer is yellow.

4. The chip package of claim 1, wherein the isolation layer has a portion on an edge of the bottom surface of the semiconductor substrate, and said portion of the isolation layer is free from coverage of the second protection layer so as to be exposed.

5. The chip package of claim 1, wherein the land conductive structure comprises a copper layer, a nickel layer, and a gold layer that are stacked in sequence.

6. The chip package of claim 1, wherein the second protection layer is in contact with the redistribution layer and the isolation layer.

7. The chip package of claim 1, wherein the redistribution layer further comprises a plurality of third sections, and the third sections are located in the first protection layer.

8. The chip package of claim 1, further comprising:
a support element located on the top surface of the semiconductor substrate and surrounding the sensing area.

9. A chip package, comprising:
a semiconductor substrate having a sensing area, a conductive pad, and a through hole, wherein the conductive pad is located in the through hole, and the sensing area and the conductive pad are located on a top surface of the semiconductor substrate;
an isolation layer located on a bottom surface of the semiconductor substrate and a sidewall that surrounds the through hole;
a redistribution layer located on the isolation layer and comprising a first section and a second section, wherein the first section is in electrical contact with the conductive pad and extends to the bottom surface of the semiconductor substrate along the sidewall of the through hole, and the second section is located on the bottom surface of the semiconductor substrate;
a first protection layer located below the isolation layer and the redistribution layer;
a second protection layer located between the redistribution layer and the first protection layer, wherein a transmittance of the first protection layer is less than a transmittance of the second protection layer; and
a land conductive structure located on the second protection layer and in electrical contact with the redistribution layer, wherein an edge of the land conductive structure extends into the first protection layer.

10. The chip package of claim 9, wherein the second protection layer is located on the first section and the second section of the redistribution layer, and is located on the isolation layer between the first section and the second section of the redistribution layer.

11. The chip package of claim 9, wherein a color of the first protection layer is different from a color of the second protection layer.

12. The chip package of claim 11, wherein the color of the first protection layer is black, and the color of the second protection layer is yellow.

13. The chip package of claim 9, wherein the isolation layer has a portion on an edge of the bottom surface of the semiconductor substrate, and said portion of the isolation layer is free from coverage of the second protection layer so as to be exposed.

14. The chip package of claim 13, wherein said portion of the isolation layer, the second protection layer that is on the first section of the redistribution layer, and the first protection layer present a stepped shape.

15. The chip package of claim 9, wherein the second protection layer is in contact with the redistribution layer and the isolation layer.

16. The chip package of claim 9, further comprising:
a support element located on the top surface of the semiconductor substrate and surrounding the sensing area.

17. A manufacturing method of a chip package, comprising:
bonding a light-transmissive plate to a semiconductor substrate by using a bonding layer;
forming a through hole in the semiconductor substrate, wherein a conductive pad of the semiconductor substrate is located in the through hole;
forming an isolation layer on a bottom surface of the semiconductor substrate and a sidewall that surrounds the through hole;
forming a redistribution layer located on the isolation layer, wherein the redistribution layer comprises a first section and a second section, the first section is in electrical contact with the conductive pad and extends to the bottom surface of the semiconductor substrate along the sidewall of the through hole, and the second section is located on the bottom surface of the semiconductor substrate;
forming a first protection layer on the first section of the redistribution layer and on the isolation layer between the first section and second section of the redistribution layer;
forming a second protection layer that is disposed along a surface of the first protection layer, wherein a transmittance of the first protection layer is less than a transmittance of the second protection layer;
forming a land conductive structure on the second protection layer and in electrical contact with the redistribution layer;
removing the bonding layer and the light-transmissive plate; and
dicing the semiconductor substrate to form at least one chip package.

18. The manufacturing method of the chip package of claim 17, wherein dicing the semiconductor substrate comprises:
forming a trench in the semiconductor substrate by using a laser; and
vertically cutting from the trench to the isolation layer on the bottom surface of the semiconductor substrate.

19. The manufacturing method of the chip package of claim 17, further comprising:
moving the chip package onto a tape.

20. A manufacturing method of a chip package, comprising:
bonding a light-transmissive plate to a semiconductor substrate by using a bonding layer;
forming a through hole in the semiconductor substrate, wherein a conductive pad of the semiconductor substrate is located in the through hole;
forming an isolation layer on a bottom surface of the semiconductor substrate and a sidewall that surrounds the through hole;
forming a redistribution layer located on the isolation layer, wherein the redistribution layer comprises a first section and a second section, the first section is in electrical contact with the conductive pad and extends to the bottom surface of the semiconductor substrate along the sidewall of the through hole, and the second section is located on the bottom surface of the semiconductor substrate;
forming a second protection layer on the redistribution layer;
forming a land conductive structure on the second protection layer and in electrical contact with the redistribution layer;
forming a first protection layer on the second protection layer and an edge of the land conductive structure, wherein a transmittance of the first protection layer is less than a transmittance of the second protection layer;
removing the bonding layer and the light-transmissive plate; and
dicing the semiconductor substrate to form at least one chip package.

21. The manufacturing method of the chip package of claim 20, wherein dicing the semiconductor substrate comprises:
forming a trench in the semiconductor substrate by using a laser; and
vertically cutting from the trench to the isolation layer on the bottom surface of the semiconductor substrate.

22. The manufacturing method of the chip package of claim 20, further comprising:
moving the chip package onto a tape.
